(19) United States
(12) Patent Application Publication
(10) Pub. No.: US 2020/0170113 A1
(43) Pub. Date: May 28, 2020

(54) HIGH DENSITY FLEXIBLE INTERCONNECT DESIGN FOR MULTI-MODE SIGNALING

(71) Applicants: Chaitanya Sreerama, Hillsboro, OR (US); Bok Eng Cheah, Bukit Gambir (MY); Jackson Chung Peng Kong, Tanjung Tokong (MY); Yew San Lim, Penang (MY); Stephen Harvey Hall, Forest Grove, OR (US); Eric C. Gantner, Portland, OR (US)

(72) Inventors: Chaitanya Sreerama, Hillsboro, OR (US); Bok Eng Cheah, Bukit Gambir (MY); Jackson Chung Peng Kong, Tanjung Tokong (MY); Yew San Lim, Penang (MY); Stephen Harvey Hall, Forest Grove, OR (US); Eric C. Gantner, Portland, OR (US)

(21) Appl. No.: 16/662,918

(22) Filed: Oct. 24, 2019

(30) Foreign Application Priority Data
Nov. 27, 2018 (MY) PI 2018002137

(51) Int. Cl. H05K 1/14; H05K 1/02; H05K 3/46; H05K 1/05

(52) U.S. Cl. CPC H05K 1/147; H05K 1/0219; H05K 1/05; H05K 1/0242; H05K 1/0298; H05K 3/4605

(57) ABSTRACT

A flexible electronic interconnect comprises a first dielectric layer including a first surface and second surface opposite the first surface; a plurality of conductors disposed on the first surface of the first dielectric layer and arranged spaced apart from each other using a conductor spacing; and a first plurality of conductive shields disposed on the second surface of the first dielectric layer and arranged spaced apart from each other using a conductive shield spacing. The first plurality of conductive shields is arranged opposite the plurality of conductors and the conductive shield spacing is arranged opposite the conductor spacing.

### PRIORITY APPLICATION

This application claims the benefit of priority to Malaysian Application Serial Number PI 2018002137, filed Nov. 27, 2018, which is incorporated herein by reference in its entirety.

### TECHNICAL FIELD

Embodiments pertain to packaging of electronic circuits. Some embodiments relate to an electrical interconnect for a flexible electronic package.

### BACKGROUND

Electronic devices (e.g., mobile phones, smart phones, tablet computers, wearables, e-readers, etc.) are continually being designed to be more flexible, compact and portable. Therefore, it is desirable to reduce one or more of the form factor, z-height, stiffness and weight of the electronic devices that are included in mobile products.

One of the concerns that can arise as things are made smaller is signal integrity issues. For example, channel crosstalk, signal reflection and signal loss are issues that need to be considered during high-speed package and printed circuit board (PCB) design. Conventional solutions that seek to mitigate signal integrity issues typically require some form of design trade-off. One or more of these design trade-offs usually constrain enabling smaller form factor and more flexible high-speed interconnects and PCBs. For example, the desire for increased signal frequency may lead to an increase in spacing between signal conductors to mitigate signal crosstalk. Therefore, a designer may need to compromise between signal speed and size. In another example, the need for flexibility in electronic interconnections may lead to an increase in size of the connectors to mitigate signal loss. Therefore, the designer may need to compromise between robustness and size.

### BRIEF DESCRIPTION OF THE DRAWINGS

FIG. 1A is an illustration of a flexible electronic interconnect in accordance with some embodiments;

FIG. 1B is an illustration of the cross section of the electronic interconnect of FIG. 1A in accordance with some embodiments;

FIG. 2 is another illustration of a cross section of a flexible electronic interconnect in accordance with some embodiments;

FIGS. 3A-3C are further illustrations of flexible electronic interconnects in accordance with some embodiments;

FIG. 4A is another illustration of a flexible electronic interconnect in accordance with some embodiments;

FIG. 4B is an illustration of the cross section of the electronic interconnect of FIG. 4A in accordance with some embodiments;

FIG. 5A is another illustration of a flexible electronic interconnect in accordance with some embodiments;

FIG. 5B is an illustration of the cross section of the electronic interconnect of FIG. 5A in accordance with some embodiments;

FIG. 6A is another illustration of a flexible electronic interconnect in accordance with some embodiments;

FIG. 6B is an illustration of the cross section of the electronic interconnect of FIG. 6A in accordance with some embodiments;

FIG. 7 is an illustration of an electronic system in accordance with some embodiments;

FIG. 8 is a flow diagram of a method of making a flexible electronic interconnect in accordance with some embodiments;

FIG. 9 is a system level diagram in accordance with some embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

The devices, systems, and methods described herein provide flexible interconnect for electronic devices with improved mechanical flexibility. The interconnect also provides high signaling bandwidth such as may be desired for an interconnection between two printed circuit boards (PCBs). This provides a high bandwidth interconnection for miniaturized and foldable applications (e.g., a dual display laptop or a flexible display for an electronic device).

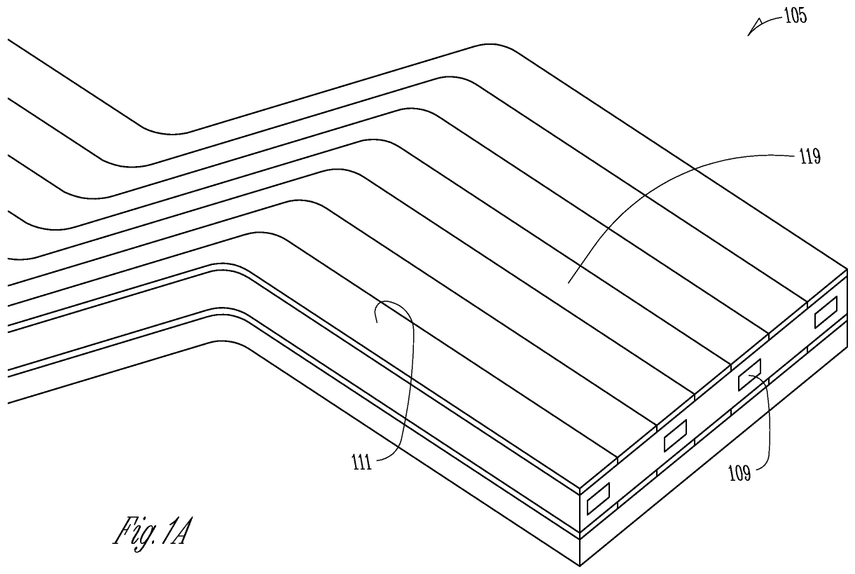

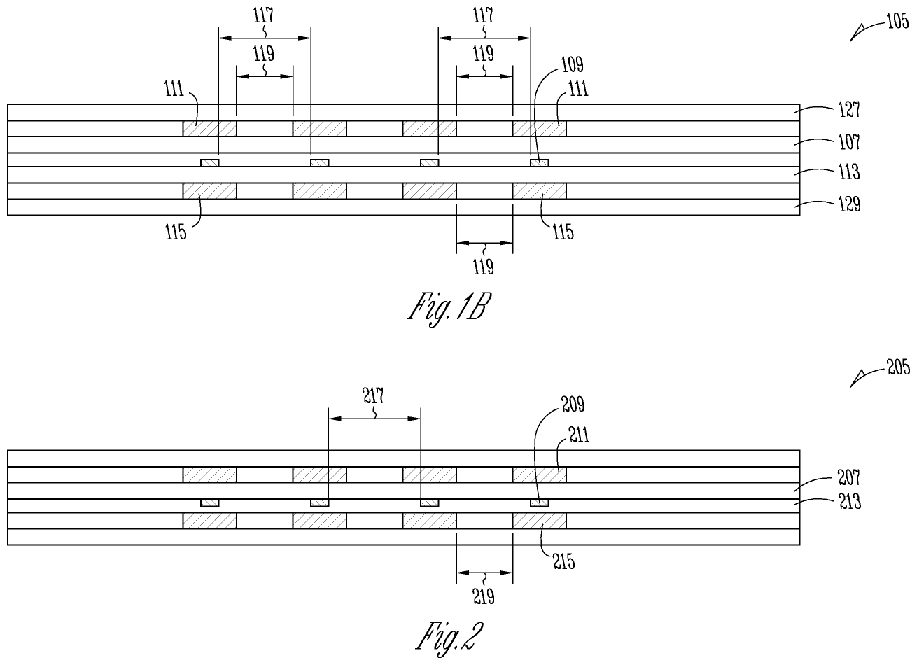

FIG. 1A is an illustration of an embodiment of a flexible electronic interconnect. In certain embodiments, the electronic interconnect 105 is a flexible printed circuit (FPC) cable. FIG. 1B is an illustration of a cross section of the electronic interconnect 105. The electronic interconnect 105 includes a dielectric layer 107, multiple conductors 109, and multiple conductive shields 111. The dielectric layer 107 can include one or more of polyimide, polyimide adhesive composites, or a liquid crystal polymer. The dielectric layer includes a first surface and a second surface opposite or opposing the first surface. The conductors 109 are disposed on the first surface (e.g., the bottom surface) of the dielectric layer 107. In certain embodiments, the conductors 109 are conductive (e.g., metal) traces to carry electrical signals. In some embodiments, each of the conductors 109 carry a single-ended electrical signal, such as for a memory interface or a Direct Media Interface(DMI) for example. In some embodiments, adjacent signal conductors are a differential conductor pair to carry a differential electrical signal, such as for a Universal Serial Bus (USB) interface, a Peripheral Component Interconnect (PCI) express interface, or an Ethernet interface for example. The conductors 109 are spaced horizontally apart from each other using a conductor spacing 117 between adjacent conductors.

The conductive shields 111 are disposed on the second surface (e.g., the top surface) of the dielectric layer 107. In certain embodiments, the conductive shields 111 are conductive traces having a greater width than the conductors 109. In certain embodiments, the conductor shields 111 have the same width as the conductors 109. The conductive shields 111 are spaced horizontally apart from each other using a conductive shield spacing 119 between adjacent conductive shields. Each conductive shield is arranged opposite a conductor, and each conductive shield spacing is arranged opposite a conductor spacing. In this way, the conductive shields 111 cover the conductors 109. The conductive shields are associated with a reference voltage. For example, the conductive shields can be electrically connected to circuit ground reference voltage (e.g., Vss) and can provide protection from electromagnetic interference (EMI) or crosstalk between conductors. In variations, one or more of the conductive shields can be electrically connected to a circuit supply reference voltage (e.g., Vcc).

In some embodiments, the electronic interconnect 105 includes a second dielectric layer 113 having a first surface and a second surface opposite the first surface. The first surface (e.g., the top surface) contacts the conductors 109. The electronic interconnect 105 can include a second set conductive shields 115 disposed on a second surface (e.g., bottom surface) of the second dielectric layer 113. As with the first set of conductive shields 111, the second set of conductive shields 115 are horizontally spaced apart from each other using the conductive shield spacing 119 between adjacent conductive shields. The spacing between shields is arranged opposite the spacing between conductors and the second set of conductive shields 115 covers the conductors 109. The second set of conductive shields 115 can be associated with the same reference voltage as the first set of conductive shields 111. In certain embodiments, a first non-conductive layer 127 (not shown in FIG. 1A) can be disposed on the first dielectric layer to contact and insulate the first set of conductive shields 111, and a second non-conductive layer 129 can be disposed on the second dielectric layer to contact and insulate the second set of conductive shields 115.

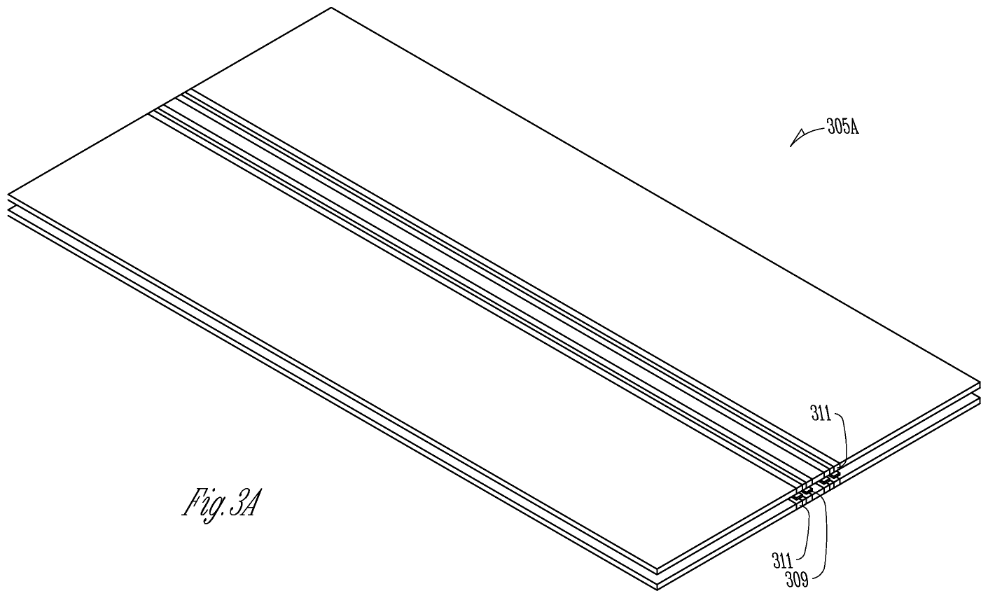

FIG. 2 is an illustration of a cross section of another embodiment of a flexible electronic interconnect. The electronic interconnect 205 includes a first dielectric layer 207, multiple conductors 209, and multiple conductive shields 211. The electronic interconnect 205 also includes a second dielectric layer 213 having a first surface and a second surface opposite the first surface. The first surface (e.g., the top surface) contacts the bottom surface of the first dielectric layer and the conductors 209 are disposed in the second dielectric layer 213. For example, the conductors may be disposed on the first layer of dielectric material and the second layer of dielectric material is formed over the conductors. A second set of conductive shields 215 is disposed on the second surface (e.g., bottom surface) of the second dielectric layer. The second set of conductive shields 215 is arranged spaced apart from each other using the conductive shield spacing. The first set of conductive shields 211 and the second set of conductive shields 215 are both arranged opposite the conductors 209. The conductive shield spacing 219 of both sets of conductive shields is arranged opposite the conductor spacing 217. As in the example embodiment of FIG. 1B, the conductive shields cover the conductors. In both example embodiments, the conductive shields all have the same width.

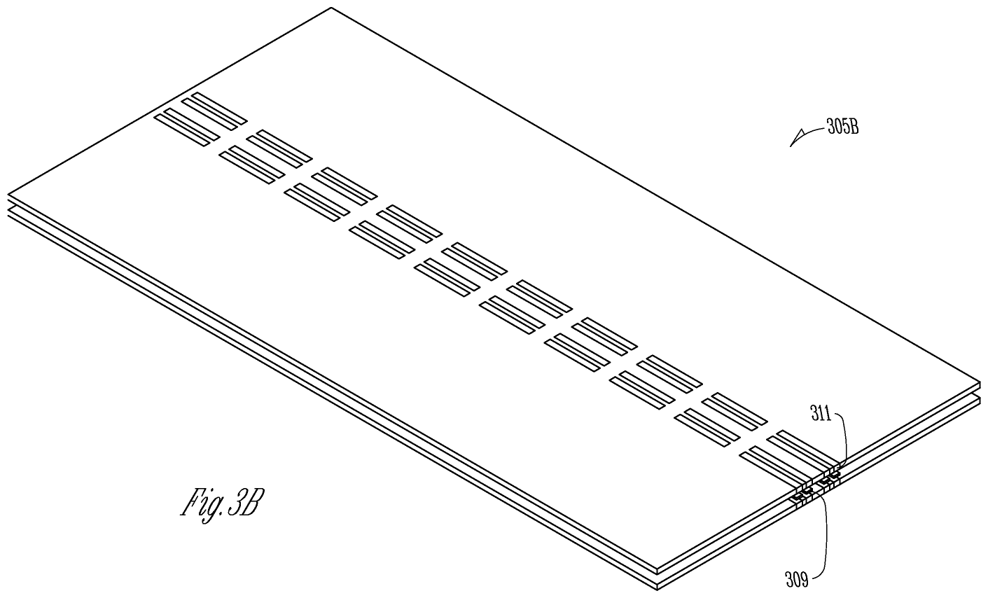

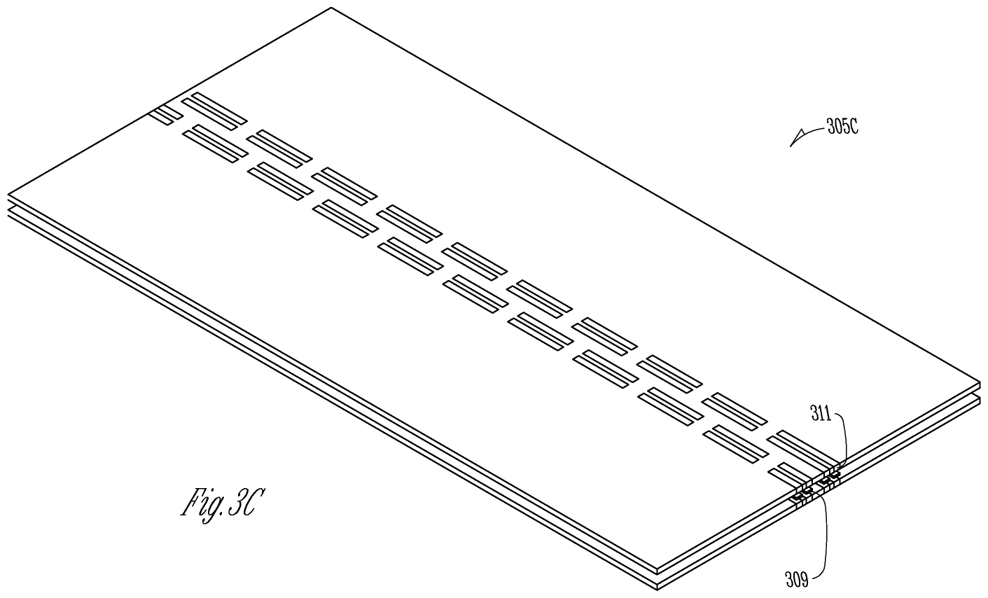

FIGS. 3A-3C are illustrations of further embodiments of flexible electronic interconnects. FIG. 3A shows a flexible electronic interconnect 305A that includes four shielded conductors 309. Only four shielded conductors are shown for simplicity, but an actual implementation may include several shielded conductors. The flexible electronic interconnect may have the construction in either of the embodiments of FIGS. 1A, 1B or FIG. 2. The example embodiment shows the conductors 309 are covered by continuous conductive shields 311. The conductors 309 and the conductive shields 311 extend in a lengthwise direction of the flexible electronic interconnect 305A.

FIG. 3B shows an example of a flexible electronic interconnect 305B in which the conductive shielding includes bridge sections that are periodically discontinued or interrupted on the top surface and the bottom surface. In some embodiments, the bridge sections of the bottom surface match the top surface and the flexible electronic interconnect includes unshielded portions. In some embodiments, the bridge sections of the bottom surface are provided where the bridge sections of the top surface are missing, and at least one-sided shielding is provided along the length of the flexible electronic interconnect 305B. This can be viewed as a “stitching” of the shielding. The discontinuous embodiment of FIG. 3B may improve electromagnetic shielding and mechanical strength of the flexible electronic interconnect 305B. FIG. 3C shows another example of a flexible electronic interconnect 305C in which the conductive shielding includes bridge sections on the top surface and the bottom surface. In this example, the discontinuities are aperiodic compared to the example embodiment of FIG. 3B and the bridge sections between adjacent shielding are not aligned. As in FIG. 3B, the conductive shielding of the bottom surface may match the top surface, or the conductive shielding of the bottom surface may be provided in segments where the conductive shielding of the top surface is missing.

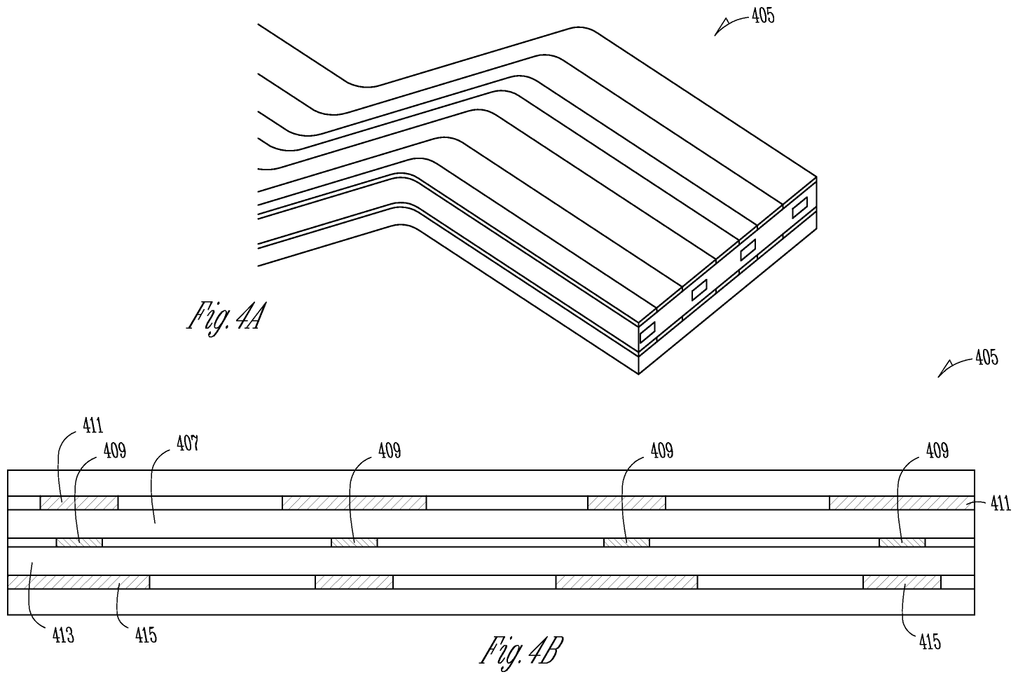

FIG. 4A is an illustration of another embodiment of a flexible electronic interconnect. The electronic interconnect 405 includes an arrangement of conductive shields that is asymmetric in width. FIG. 4B is an illustration of the cross section of the electronic interconnect 405. The electronic interconnect 405 includes two dielectric layers 407 and 413, multiple conductors 409, and two layers of conductive shields 411 and 415; one layer disposed on each of the dielectric layers. Each of the layers of the conductive shields includes shields of two different widths. As shown in FIG. 4B, conductive shields with the first shield width are arranged opposite conductive shields with the second shield width. The conductive shields are arranged on opposite sides of the conductors. The shielding using asymmetric shield widths reduces the metal density of the electronic interconnect while preserving electrical performance of the interconnect.

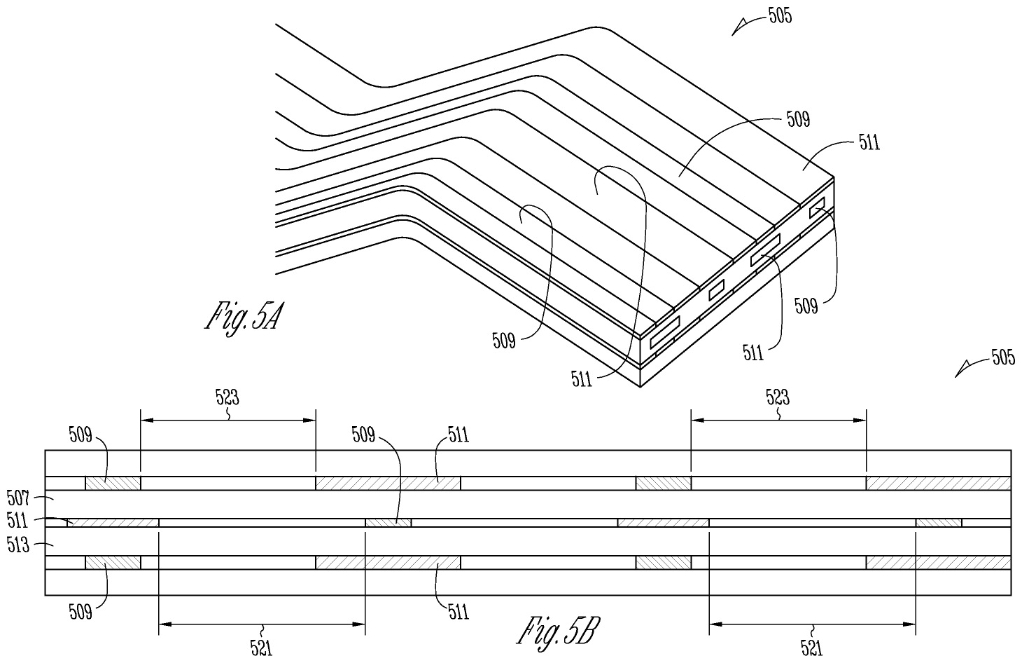

FIG. 5A is an illustration of another embodiment of a flexible electronic interconnect. The surface of the electronic interconnect 505 shows both conductors 509 and conductive shields 511. FIG. 5B is an illustration of a cross section of the electronic interconnect 505. The electronic interconnect 505 includes a first dielectric layer 507. A first set of conductors 509 and conductive shields 511 are arranged on the bottom surface of the dielectric layer 507. The conductors are alternated with the conductive shields and are spaced apart using a first spacing 521. A second set of conductors 509 and conductive shields 511 are arranged on the top surface of the dielectric layer 507. The conductors alternate with the conductive shields and are spaced apart using a second spacing 523. Conductors of the first set are arranged opposite conductive shields 511 of the second set, and conductive shields 511 of the first set are arranged opposite the conductors 509 of the second set. The first spacings 521 are arranged opposite the second spacings 523.

In some embodiments, the electronic interconnect 505 includes a second dielectric layer 513. The top surface of the second dielectric layer 513 contacts the first set of conductors 509 and conductive shields 511 arranged on the bottom surface of the first dielectric layer 507. A third set of conductors 509 and conductive shields 511 are arranged on the bottom surface of the second dielectric layer 513. The conductors 509 of the third set are arranged opposite the conductive shields 511 of the first set, and the conductive shields 511 of the first set are arranged opposite the conductors 509 of the third set. The shielding prevents cross talk between the three sets of conductors 509 of the electronic interconnect 505. The alternating placement of the conductor and shield traces enables a more compact design and can increase input-output (I/O) density of the electronic interconnect 505 with the same routing footprint as the embodiments previously described herein and preserves the mechanical and flexibility benefits provided by the shield and conductor spacing of the embodiments.

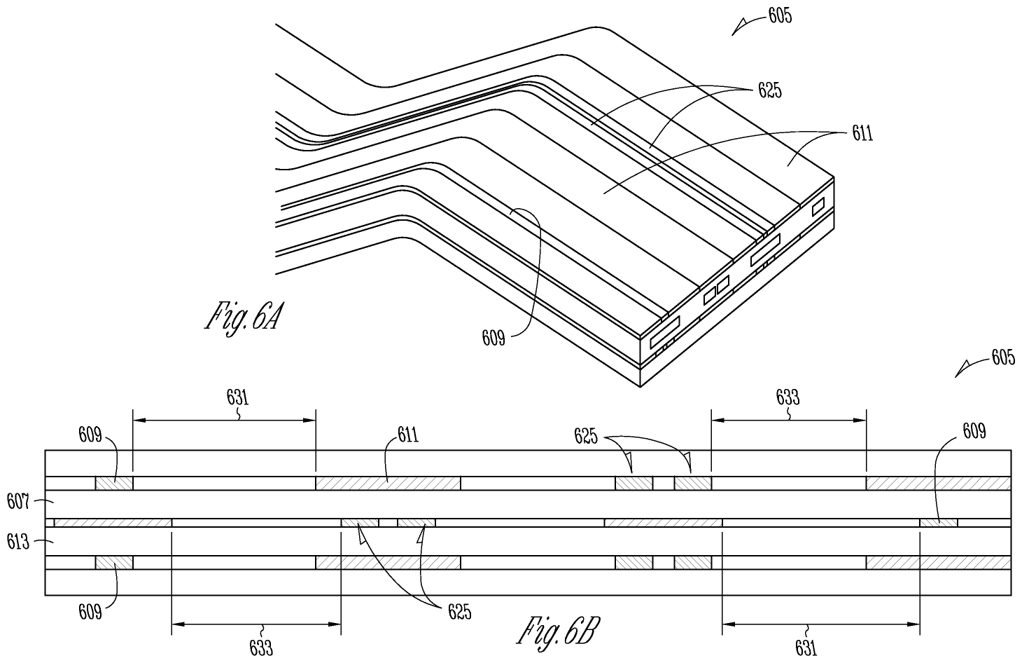

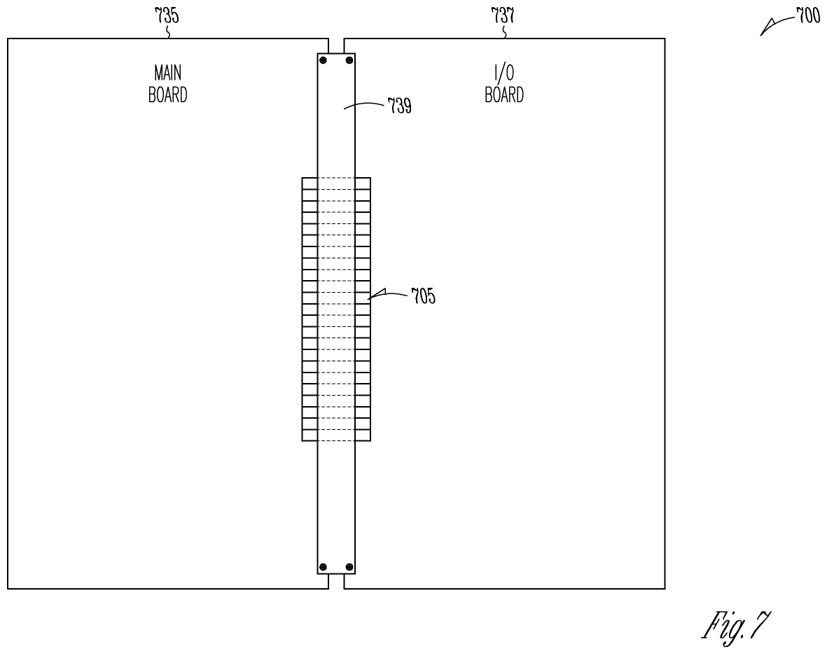

FIG. 6A is an illustration of another embodiment of a flexible electronic interconnect. The surface of the electronic interconnect 605 shows both conductors 609 and conductive shields 611. The difference from the example embodiment of FIG. 6A is that electronic interconnect 605 includes pairs of conductors 609 that alternate with the conductive shields 611. FIG. 6B is an illustration of a cross section of the electronic interconnect 605 of FIG. 6A.

The electronic interconnect 605 includes two dielectric layers 607 and 613 and three layers of conductors and conductive shields. In the example embodiment of FIG. 6B, each of the layers includes a conductor pair 625 that is associated with a differential electrical signal pair, and a single conductor 609 that is associated with a single-ended electrical signal. The conductor pairs of each layer are arranged between conductive shields of each layer. Each layer of shields and conductors includes both single conductors 609 between conductive shields and conductor pairs 625 between conductive shields. Thus, the example embodiment of FIG. 6B provides hybrid signal routing of both single-ended and differential electrical signals within the same electronic interconnect.

Each dielectric layer includes two opposing surfaces. The conductors (single or pair) arranged on the first surface of a dielectric layer are arranged opposite the conductive shields arranged on the second surface of the dielectric layer. The conductors are spaced between conductive shields using a conductor-to-shield spacing 631 and a conductor-pair-to-shield spacing 633. The spacings of the first surface of a dielectric layer are arranged opposite the spacings of the second surface of the dielectric layer.

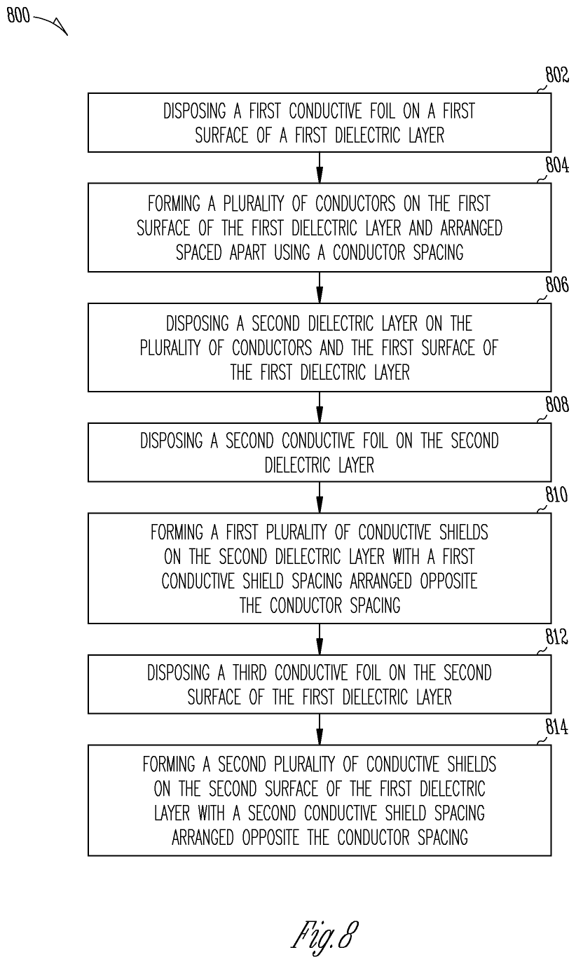

FIG. 7 is an illustration of an embodiment of an electronic system. The electronic system 700 includes a first PCB 735 and a second PCB 737. Each of the first and second PCBs include at least one conductive trace. The electronic system 700 also includes a flexible electronic interconnect 705 that provides electrical continuity to the conductive trace of the first PCB 735 and the conductive trace of the second PCB 737. The flexible electronic interconnect 705 can be any embodiment of the flexible electronic interconnects described herein.

The PCBs can be mechanically coupled by a movable mechanism 739 so that the electronic system can be folded. In some embodiments, the movable mechanism is a hinge. The flexible electronic interconnect 705 may pass through at least a portion of the moveable mechanism to electrically couple the two PCBs.

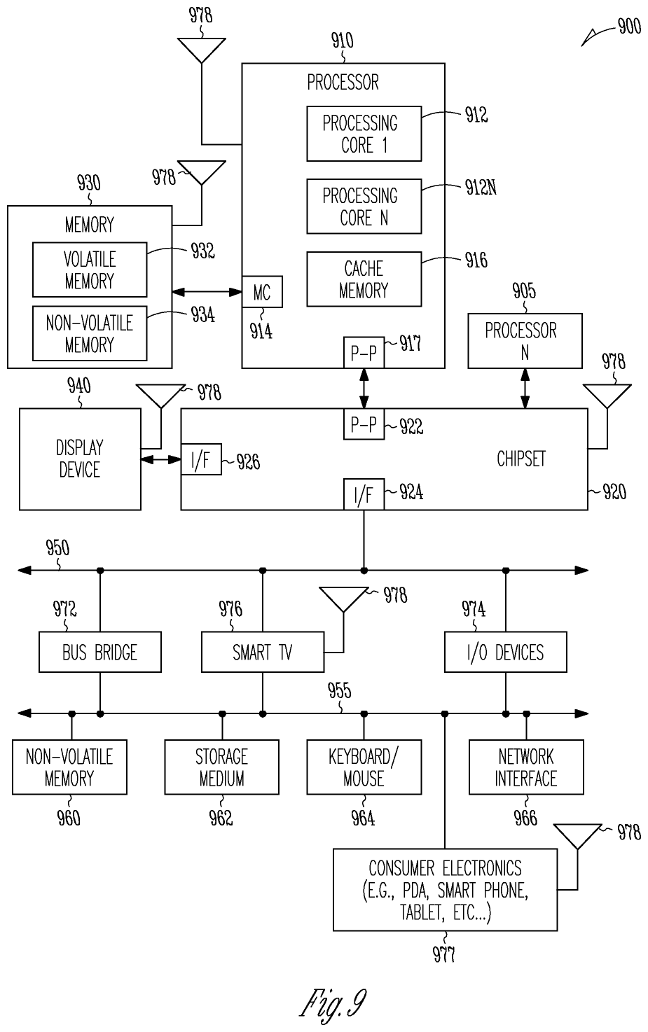

FIG. 8 is a flow diagram of an example of method 800 of making a flexible electronic interconnect. At 802, a first conductive foil is disposed on a first surface of a first dielectric layer. The first dielectric layer may comprise polyimide and the first conductive foil may comprise a metal (e.g., copper or aluminum). In certain embodiments, a hot-press lamination process is used to dispose the first conductive foil onto the first dielectric layer.

At 804, multiple conductors are formed on the first surface of the first dielectric layer and arranged spaced apart using a conductor spacing. In certain embodiments, the conductors are formed using a patterning and etching process. In the example embodiment of FIG. 1B, conductors 109 are shown formed on the bottom surface of dielectric layer 107.

Returning to FIG. 8 at 806, a second dielectric layer is disposed on the conductors and the first surface of the first dielectric layer. In FIG. 1B, dielectric layer 113 is disposed on the conductors 109 and the bottom surface of dielectric layer 107. At 808, a second conductive foil is disposed on the second dielectric layer. The second dielectric layer and the second conductive foil may be disposed using the hot-press lamination process.

At 810, a first set of conductive shields are formed on the second dielectric layer with a first conductive shield spacing. The shields may be formed using the patterning and etching process. The conductor shield spacing is arranged opposite the conductor spacing. In FIG. 1B, conductive shields 115 are shown formed on the bottom surface of dielectric layer 113. Conductive shield spacing 119 is shown opposite conductor spacing 117.

At 812, a third conductive foil is disposed on the second surface of the first dielectric layer. At 814, a second set of conductive shields are formed on the second surface of the first dielectric layer, such as by using the patterning and etching process. The second set of conductive shields are formed with a second conductive shield spacing arranged opposite the conductor spacing. In FIG. 1B, conductive shields 111 are shown formed on the top surface of the first dielectric layer with the conductive shield spacing 119 shown opposite conductor spacing 117.

The devices, systems, and methods described herein provide a flexible electronic interconnect for electronic devices with improved mechanical flexibility while still providing high signaling bandwidth.

FIG. 9 illustrates a system level diagram, according to one embodiment of the invention. For instance, FIG. 9 depicts an example of an electronic device (e.g., system) that can include one or more of the flexible electronic interconnects as described in the present disclosure. In one embodiment, system 900 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 900 is a system on a chip (SOC) system. In one example, two or more systems as shown in FIG. 9 may be coupled together, or two or more portions of the system may be coupled together, using one or more flexible electronic interconnects as described in the present disclosure.

In one embodiment, processor 910 has one or more processing cores 912 and 912N, where N is a positive integer and 912N represents the Nth processor core inside processor 910. In one embodiment, system 900 includes multiple processors including 910 and 905, where processor 905 has logic similar or identical to the logic of processor 910. In some embodiments, processing core 912 includes, but is not limited to, pre-fetch logic to fetch instructions, decode logic to decode the instructions, execution logic to execute instructions and the like. In some embodiments, processor 910 has a cache memory 916 to cache instructions and/or data for system 900. Cache memory 916 may be organized into a hierarchal structure including one or more levels of cache memory.

In some embodiments, processor 910 includes a memory controller 914, which is operable to perform functions that enable the processor 910 to access and communicate with memory 930 that includes a volatile memory 932 and/or a non-volatile memory 934. In some embodiments, processor 910 is coupled with memory 930 and chipset 920. Processor 910 may also be coupled to a wireless antenna 978 to communicate with any device configured to transmit and/or receive wireless signals. In one embodiment, the wireless antenna interface 978 operates in accordance with, but is not limited to, the IEEE 802.11 standard and its related family, Home Plug AV (HPAV), Ultra-Wide Band (UWB), Bluetooth, WiMax, or any form of wireless communication protocol.

In some embodiments, volatile memory 932 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 934 includes, but is not limited to, flash memory, phase change memory (PCM), read-only memory (ROM), electrically erasable programmable read-only memory (EEPROM), or any other type of non-volatile memory device.

Memory 930 stores information and instructions to be executed by processor 910. In one embodiment, memory 930 may also store temporary variables or other intermediate information while processor 910 is executing instructions. In the illustrated embodiment, chipset 920 connects with processor 910 via Point-to-Point (PtP or P-P) interfaces 917 and 922. Chipset 920 enables processor 910 to connect to other elements in system 900. In some embodiments of the invention, interfaces 917 and 922 operate in accordance with a PtP communication protocol such as the Intel® QuickPath Interconnect (QPI) or the like. In other embodiments, a different interconnect may be used.

In some embodiments, chipset 920 is operable to communicate with processor 910, 905N, display device 940, and other devices 972, 976, 974, 960, 962, 964, 966, 977, etc. Buses 950 and 955 may be interconnected together via a bus bridge 972. Chipset 920 connects to one or more buses 950 and 955 that interconnect various elements 974, 960, 962, 964, and 966. Chipset 920 may also be coupled to a wireless antenna 978 to communicate with any device configured to transmit and/or receive wireless signals. Chipset 920 connects to display device 940 via interface (I/F) 926. Display 940 may be, for example, a liquid crystal display (LCD), a plasma display, cathode ray tube (CRT) display, or any other form of visual display device. In some embodiments of the invention, processor 910 and chipset 920 are merged into a single SOC. In one embodiment, chipset 920 couples with (e.g., via interface 924) a non-volatile memory 960, a mass storage medium 962, a keyboard/mouse 964, network interface 966, I/O devices 974, smart TV 976, and consumer electronics 977 (e.g., PDA, Smart Phone, Tablet, etc.).

In one embodiment, mass storage medium 962 includes, but is not limited to, a solid state drive, a hard disk drive, a universal serial bus flash memory drive, or any other form of computer data storage medium. In one embodiment, network interface 966 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra-Wide Band (UWB), Bluetooth, WiMax, or any form of wireless communication protocol.

While the modules shown in FIG. 9 are depicted as separate blocks within the system 900, the functions performed by some of these blocks may be integrated within a single semiconductor circuit or may be implemented using two or more separate integrated circuits. For example, although cache memory 916 is depicted as a separate block within processor 910, cache memory 916 (or selected aspects of 916) can be incorporated into processor core 912.

### ADDITIONAL DESCRIPTION AND EXAMPLES

Example 1 includes subject matter (such as flexible electronic interconnect) comprising a first dielectric layer including a first surface and second surface opposite the first surface; a plurality of conductors disposed on the first surface of the first dielectric layer and arranged spaced apart from each other using a conductor spacing; and a first plurality of conductive shields disposed on the second surface of the first dielectric layer and arranged spaced apart from each other using a conductive shield spacing, wherein the first plurality of conductive shields is arranged opposite the plurality of conductors and the conductive shield spacing is arranged opposite the conductor spacing.

In Example 2, the subject matter of Example 1 optionally includes a second dielectric layer including a first surface and a second surface opposite the first surface, wherein the first surface of the second dielectric layer contacts the plurality of conductors.

In Example 3, the subject matter of Example 2 optionally includes a second plurality of conductive shields disposed on the second surface of the second dielectric layer and arranged spaced apart from each other using the conductive shield spacing, wherein the second plurality of conductive shields is arranged opposite the plurality of conductors and the conductive shield spacing of the second plurality of conductive shields is arranged opposite the conductor spacing.

In Example 4, the subject matter Example 3 optionally includes the first plurality of conductive shields including a first shield width and a second shield width, wherein conductive shields of the first plurality of conductive shields with the first shield width are arranged opposite conductive shields of the second plurality of conductive shields with the second shield width.

In Example 5, the subject matter of one or both of Example 3 and 4 optionally include the flexible electronic interconnect having a length, the first plurality of conductive shields and the second plurality of conductive shields extend in a lengthwise direction on the flexible electronic interconnect, and the first plurality of conductive shields and the second plurality of conductive shields include one or more discontinuities in the conductive shields.

In Example 6, the subject matter of one or any combination of Examples 1-5 optionally includes a second dielectric layer including a first surface and a second surface opposite the first surface, wherein the first surface of the second dielectric layer contacts the first surface of the first dielectric layer and the plurality of conductors is disposed in the second dielectric layer; and a second plurality of conductive shields disposed on the second surface of the second dielectric layer and arranged spaced apart from each other using the conductive shield spacing, wherein the second plurality of conductive shields is arranged opposite the plurality of conductors and the conductive shield spacing of the second plurality of conductive shields is arranged opposite the conductor spacing.

In Example 7, the subject matter of one or any combination of Examples 1-6 optionally includes the first plurality of conductive shields being associated to one of a circuit ground reference voltage or a circuit supply reference voltage.

In Example 8, the subject matter of one or any combination of Examples 1-7 optionally includes the plurality of conductors including a first electrical signal conductor and a second electrical signal conductor that are associated with a differential pair signal.

In Example 9, the subject matter or Example 8 optionally includes the first plurality of conductive shields including a first conductive shield and a second conductive shield disposed on the second surface of the first dielectric layer and arranged opposite the first and second electrical signal conductors, respectively, and wherein the first and second conductive shields include bridge sections that are periodically spaced to cover the first and second signal conductors.

In Example 10, the subject matter or Example 9 optionally includes bridge sections that are periodically spaced to cover the first electrical signal conductor are not aligned with the bridge sections that are periodically spaced to cover the second electrical signal conductor.

In Example 11, the subject matter of one or any combination of Examples 1-10 optionally includes the plurality of conductors including a first electrical signal conductor and a second electrical signal conductor that are each associated with a single-ended electrical signal.

In Example 12, the subject matter of one or ay combination of Examples 1-11 optionally includes the first dielectric layer including at least one of polyimide, polyimide adhesive composites, or a liquid crystal polymer.

Example 13 includes subject matter (such as an electronic system) or can optionally be combined with one or any combination of Examples 1-12 to include such subject matter, comprising a first printed circuit board (PCB) including at least one conductive trace; a second PCB including at least one conductive trace; and a flexible electronic interconnect providing electrical continuity to the at least one conductive trace of the first PCB and the least one conductive trace of the second PCB. The flexible electronic interconnect includes: a first dielectric layer including a first surface and second surface opposite the first surface; a plurality of conductors disposed on the first surface of the first dielectric layer and arranged spaced apart from each other using a conductor spacing; and a first plurality of conductive shields disposed on the second surface of the first dielectric layer and arranged spaced apart from each other using a conductive shield spacing, wherein the first plurality of conductive shields is arranged opposite the plurality of conductors and the conductive shield spacing is arranged opposite the conductor spacing.

In Example 14, the subject matter of Example 13 optionally includes a movable mechanism, wherein the moveable mechanism mechanically couples the first PCB and the second PCB, and the flexible electronic interconnect passes through at least a portion of the moveable mechanism.

In Example 15, the subject matter of one or both of Examples 13 and 14 optionally includes a movable mechanism including a hinge that mechanically couples the first PCB and the second PCB, and the flexible electronic interconnect passes through the hinge.

In Example 16, the subject matter of one or any combination of Examples 13-15 optionally includes a second dielectric layer including a first surface and a second surface opposite the first surface, wherein the first surface of the second dielectric layer contacts the plurality of conductors; and a second plurality of conductive shields disposed on the second surface of the second dielectric layer and arranged spaced apart from each other using the conductive shield spacing, wherein the second plurality of conductive shields is arranged opposite the plurality of conductors and the conductive shield spacing of the second plurality of conductive shields is arranged opposite the conductor spacing.

In Example 17. The subject matter of Example 16 optionally includes a first non-conductive layer disposed on the second surface of the first dielectric layer and contacting the first plurality of conductive shields, and a second non-conductive layer disposed on the second surface of the second dielectric layer and contacting the second plurality of conductive shields.

Example 18 includes subject matter (such as a flexible electronic interconnect) or can optionally be combined with one or any combination of Examples 1-17 to include such subject matter, comprising a first dielectric layer including a first surface and second surface opposite the first surface; a first plurality of conductors disposed on the first surface of the first dielectric layer; a first plurality of conductive shields disposed on the first surface of the first dielectric layer; a second plurality of conductors disposed on the second surface of the first dielectric layer; a second plurality of conductive shields disposed on the second surface of the first dielectric layer. The conductive shields of the second plurality of conductive shields of the second surface are arranged opposite conductors of the first plurality of conductors of the first surface, and conductors of the second plurality of conductors of the second surface are arranged opposite conductive shields of the first plurality of conductive shields of the first surface.

In Example 19, the subject matter of Example 18 optionally includes a second dielectric layer including a first surface and a second surface opposite the first surface, wherein the first surface of the second dielectric layer contacts the first plurality of conductors and the first plurality of conductive shields; a third plurality of conductors disposed on the second surface of the second dielectric layer; a third plurality of conductive shields disposed on the second surface of the second dielectric layer. The conductive shields of the third plurality of conductive shields of the second surface of the second dielectric layer are arranged opposite the first plurality of conductors of the first surface of the first dielectric layer, and conductors of the third plurality of conductors of the second surface of the second dielectric layer are arranged opposite the first plurality of conductive shields of the first surface of the first dielectric layer.

In Example 20, the subject matter of one of both of Examples 18 and 19 optionally include conductors of the first plurality of conductors of the first surface of the first dielectric layer that alternate with conductive shields of the first plurality of conductive shields of the first surface of the first dielectric layer.

In Example 21, the subject matter of Example 20 optionally includes the conductive shields of the first plurality of conductive shields of the first surface of the first dielectric layer are spaced apart from the conductors of the first plurality of conductors of the first surface of the first dielectric layer using a first spacing, the conductive shields of the second plurality of conductive shields of the second surface of the first dielectric layer are spaced apart from the conductors of the second plurality of conductors of the second surface of the first dielectric layer using a second spacing; and the second spacing of the second surface of the first dielectric layer is arranged opposite the first spacing of the first surface of the first dielectric layer.

In Example 22, the subject matter of one or any combination of Examples 18-21 optionally includes pairs of conductors of the first plurality of conductors of the first surface of the first dielectric layer alternate with conductive shields of the first plurality of conductive shields of the first surface of the first dielectric layer.

These non-limiting examples can be combined in any permutation or combination. The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

1. A flexible electronic interconnect comprising:
a first dielectric layer including a first surface and second surface opposite the first surface;
a plurality of conductors disposed on the first surface of the first dielectric layer and arranged spaced apart from each other using a conductor spacing; and
a first plurality of conductive shields disposed on the second surface of the first dielectric layer and arranged spaced apart from each other using a conductive shield spacing, wherein the first plurality of conductive shields is arranged opposite the plurality of conductors and the conductive shield spacing is arranged opposite the conductor spacing.

2. The flexible electronic interconnect of claim 1, including a second dielectric layer including a first surface and a second surface opposite the first surface, wherein the first surface of the second dielectric layer contacts the plurality of conductors.

3. The flexible electronic interconnect of claim 2, including a second plurality of conductive shields disposed on the second surface of the second dielectric layer and arranged spaced apart from each other using the conductive shield spacing, wherein the second plurality of conductive shields is arranged opposite the plurality of conductors and the conductive shield spacing of the second plurality of conductive shields is arranged opposite the conductor spacing.

4. The flexible electronic interconnect of claim 3, wherein the first plurality of conductive shields includes a first shield width and a second shield width, wherein conductive shields of the first plurality of conductive shields with the first shield width are arranged opposite conductive shields of the second plurality of conductive shields with the second shield width.

5. The flexible electronic interconnect of claim 3, wherein the flexible electronic interconnect has a length, the first plurality of conductive shields and the second plurality of conductive shields extend in a lengthwise direction on the flexible electronic interconnect, and the first plurality of conductive shields and the second plurality of conductive shields include one or more discontinuities in the conductive shields.

6. The flexible electronic interconnect of claim 1, including:
a second dielectric layer including a first surface and a second surface opposite the first surface, wherein the first surface of the second dielectric layer contacts the first surface of the first dielectric layer and the plurality of conductors is disposed in the second dielectric layer; and
a second plurality of conductive shields disposed on the second surface of the second dielectric layer and arranged spaced apart from each other using the conductive shield spacing, wherein the second plurality of conductive shields is arranged opposite the plurality of conductors and the conductive shield spacing of the second plurality of conductive shields is arranged opposite the conductor spacing.

7. The flexible electronic interconnect of claim 1, wherein the first plurality of conductive shields is associated to one of a circuit ground reference voltage or a circuit supply reference voltage.

8. The flexible electronic interconnect of claim 1, wherein the plurality of conductors includes a first electrical signal conductor and a second electrical signal conductor that are associated with a differential pair signal.

9. The flexible electronic interconnect of claim 8, wherein the first plurality of conductive shields includes a first conductive shield and a second conductive shield disposed on the second surface of the first dielectric layer and arranged opposite the first and second electrical signal conductors, respectively, and wherein the first and second conductive shields include bridge sections that are periodically spaced to cover the first and second signal conductors.

10. The flexible electronic interconnect of claim 9, wherein the bridge sections that are periodically spaced to cover the first electrical signal conductor are not aligned with the bridge sections that are periodically spaced to cover the second electrical signal conductor.

11. The flexible electronic interconnect of claim 1, wherein the plurality of conductors includes a first electrical signal conductor and a second electrical signal conductor hat are each associated with a single-ended electrical signal.

12. The flexible electronic interconnect of claim 1, wherein the first dielectric layer includes at least one of polyimide, polyimide adhesive composites, or a liquid crystal polymer.

13. An electronic system comprising:
a first printed circuit board (PCB) including at least one conductive trace;
a second PCB including at least one conductive trace; and
a flexible electronic interconnect providing electrical continuity to the at least one conductive trace of the first PCB and the least one conductive trace of the second PCB, wherein the flexible electronic interconnect includes:
a first dielectric layer including a first surface and second surface opposite the first surface;
a plurality of conductors disposed on the first surface of the first dielectric layer and arranged spaced apart from each other using a conductor spacing; and
a first plurality of conductive shields disposed on the second surface of the first dielectric layer and arranged spaced apart from each other using a conductive shield spacing, wherein the first plurality of conductive shields is arranged opposite the plurality of conductors and the conductive shield spacing is arranged opposite the conductor spacing.

14. The electronic system of claim 13, including a movable mechanism, wherein the moveable mechanism mechanically couples the first PCB and the second PCB, and the flexible electronic interconnect passes through at least a portion of the moveable mechanism,

15. The electronic system of claim 14, wherein the movable mechanism includes a hinge that mechanically couples the first PCB and the second PCB, and the flexible electronic interconnect passes through the hinge.

16. The flexible electronic interconnect of claim 13, including:
a second dielectric layer including a first surface and a second surface opposite the first surface, wherein the first surface of the second dielectric layer contacts the plurality of conductors; and
a second plurality of conductive shields disposed on the second surface of the second dielectric layer and arranged spaced apart from each other using the conductive shield spacing, wherein the second plurality of conductive shields is arranged opposite the plurality of conductors and the conductive shield spacing of the second plurality of conductive shields is arranged opposite the conductor spacing.

17. The electronic system of claim 16, including a first non-conductive layer disposed. on the second surface of the first dielectric layer and contacting the first plurality of conductive shields, and a second non-conductive layer disposed on the second surface of the second dielectric layer and contacting the second plurality of conductive shields.

18. A flexible electronic interconnect comprising:
a first dielectric layer including a first surface and second surface opposite the first surface;
a first plurality of conductors disposed on the first surface of the first dielectric layer;
a first plurality of conductive shields disposed on the first surface of the first dielectric layer;
a second plurality of conductors disposed on the second surface of the first dielectric layer;
a second plurality of conductive shields disposed on the second surface of the first dielectric layer; and
wherein conductive shields of the second plurality of conductive shields of the second surface are arranged opposite conductors of the first plurality of conductors of the first surface, and conductors of the second plurality of conductors of the second surface are arranged opposite conductive shields of the first plurality of conductive shields of the first surface.

19. The flexible electronic interconnect of claim 18, including:
a second dielectric layer including a first surface and a second surface opposite the first surface, wherein the first surface of the second dielectric layer contacts the first plurality of conductors and the first plurality of conductive shields;
a third plurality of conductors disposed on the second surface of the second dielectric layer;
a third plurality of conductive shields disposed on the second surface of the second dielectric layer; and
wherein conductive shields of the third plurality of conductive shields of the second surface of the second dielectric layer are arranged opposite the first plurality of conductors of the first surface of the first dielectric layer, and conductors of the third plurality of conductors of the second surface of the second dielectric layer are arranged opposite the first plurality of conductive shields of the first surface of the first dielectric layer.

20. The flexible electronic interconnect of claim 18, wherein conductors of the first plurality of conductors of the first surface of the first dielectric layer alternate with conductive shields of the first plurality of conductive shields of the first surface of the first dielectric layer.

21. The flexible electronic interconnect of claim 20,
wherein the conductive shields of the first plurality of conductive shields of the first surface of the first dielectric layer are spaced apart from the conductors of the first plurality of conductors of the first surface of the first dielectric layer using a first spacing;
wherein the conductive shields of the second plurality of conductive shields of the second surface of the first dielectric layer are spaced apart from the conductors of the second plurality of conductors of the second surface of the first dielectric layer using a second spacing; and
wherein the second spacing of the second surface of the first dielectric layer is arranged opposite the first spacing of the first surface of the first dielectric layer.

22. The flexible electronic interconnect of claim 18, wherein pairs of conductors of the first plurality of conductors of the first surface of the first dielectric layer alternate with conductive shields of the first plurality of conductive shields of the first surface of the first dielectric layer.
